(19) United States
(12) Patent Application Publication
(10) Pub. No.: US 2011/0186123 A1
(43) Pub. Date: Aug. 4, 2011

(54) SUBSTRATE WITH INSULATION LAYER AND THIN-FILM SOLAR CELL

(75) Inventor: Atsushi MUKAI, Ashigara-kami-gun (JP)

(73) Assignee: FUJIFILM Corporation, Tokyo (JP)

(21) Appl. No.: 13/013,489

(22) Filed: Jan. 25, 2011

(30) Foreign Application Priority Data
Feb. 1, 2010 (JP) 2010-020158

(51) Int. Cl. H01L 31/0224; B32B 15/04

(52) U.S. Cl. 136/256; 428/469; 428/472.2; 428/336

(57) ABSTRACT

A substrate with an insulation layer has at least one metal base and an insulation layer. The insulation layer is laminated on a surface of the metal base. A linear thermal expansion coefficient of a material that constitutes the insulation layer is 8 ppm/K or less, and a linear thermal expansion coefficient of a material that constitutes the metal base is 17 ppm/K or more. The linear thermal expansion coefficient on the front surface of the insulation layer on a side opposite to the metal base is 6-15 ppm/K.

### BACKGROUND OF THE INVENTION

The present invention relates to a substrate with insulation layer for use in thin-film solar cells, and to a thin-film solar cell. In particular, it relates to a substrate with insulation layer for use in thin-film solar cells which inhibits peeling of the layers that constitute the thin-film solar cell, and to a thin-film solar cell which uses this substrate with insulation layer.

Recently, a great deal of research on solar cells has been conducted. Solar cell modules forming a solar cell each comprise a solar cell submodule including a number of series-connected laminate-structured photoelectric conversion elements formed on a substrate, each of which is essentially composed of a semiconductor photoelectric conversion layer generating current by light absorption sandwiched by an back electrode (bottom or lower electrode) and a transparent electrode (upper electrode). Presently, there remains an issue of reducing the costs of the solar cell modules in the market of the solar cell modules.

As the next generation of solar cell modules, those which use a CIGS layer in the photoelectric conversion layer are being studied. Solar cell modules which use CIGS layers can be made from thin films because they have relatively high efficiency and high solar absorptivity, and as a result, materials costs can be reduced. For this reason, they have been studied a great deal as a candidate for low-cost solar cell modules.

Also, as a substrate which constitutes a solar cell module, a substrate wherein at least one insulation layer made from Al₂O₃ or SiO₂ is formed on top of an aluminum substrate has been proposed (refer to U.S. Pat. No. 7,053,294).

In the solar cell disclosed in U.S. Pat. No. 7,053,294, as shown in FIG. 4, for example, an insulation layer of Al₂O₃ is formed on top of an aluminum substrate, and on top of this Al₂O₃ insulation layer, a back metal contact layer made of molybdenum is formed. Additionally, a CIGS thin film is formed on top of the back metal contact layer. A II-VI film is formed on top of the CIGS thin film. A transparent conductive oxide layer (TCO layer) is formed on top of this II-VI film. In addition, a grid electrode is formed on top of the transparent conductive oxide layer. The Al₂O₃ insulation layer is exemplified by one formed by anodizing the aluminum substrate.

Also, the aluminum substrate of U.S. Pat. No. 7,053,294 is one that is flexible.

Because integration is possible by using Al₂O₃ as the insulation layer on top of a substrate, as in the solar cell disclosed in U.S. Pat. No. 7,053,294, the manufacturing cost of the solar cell can be reduced. Also, since the substrate disclosed in U.S. Pat. No. 7,053,294 is flexible, the roll-to-roll process can be employed, and costs can be further reduced.

### SUMMARY OF THE INVENTION

However, in a solar cell module, when a substrate having the Al₂O₃ insulation layer according to U.S. Pat. No. 7,053,294 is used, if a CIGS layer is formed after the molybdenum film is formed as a back electrode on top of the Al₂O₃ (alumina) insulation layer of the substrate of U.S. Pat. No. 7,053,294, there is the problem that the molybdenum layer or the CIGS layer peels.

This is because the linear thermal expansion coefficients of the molybdenum layer and the CIGS layer are approximately 10 ppm/K, which is about the same as glass. In contrast, the aluminum that constitutes the substrate has a linear thermal expansion coefficient of approximately 25 ppm/K, which differs greatly from the linear thermal expansion coefficient of the Al₂O₃ formed by anodization of about 5 ppm/K.

For this reason, strain occurs due to the rise and fall of temperature when the molybdenum film is formed and due to the rise and fall of temperature when the CIGS layer is formed, and there is the problem that the molybdenum film or CIGS layer ends up peeling.

The objective of the present invention is to resolve the problems based on the aforementioned prior art, and to provide a substrate with insulation layer for use in thin-film solar cells which can inhibit peeling of the layers that constitute the thin-film solar cell, and a thin-film solar cell which uses this substrate with insulation layer.

To achieve the above objective, a first aspect of the present invention provides a substrate with an insulation layer, comprising: at least one metal base; and an insulation layer laminated on at least one surface of the at least one metal base, wherein a linear thermal expansion coefficient of a first material that constitutes the insulation layer is 8 ppm/K or less, a linear thermal expansion coefficient of a second material that constitutes the at least one metal base is 17 ppm/K or more, and a linear thermal expansion coefficient on a front surface of the insulation layer on a side opposite to the at least one metal base is 6-15 ppm/K.

It is preferred that the insulation layer is made of alumina.

It is preferred that the at least one metal base comprises a first metal base which contacts the insulation layer and which is made of aluminum.

It is preferred that the insulation layer is an anodized film formed by anodizing the second material made of aluminum.

It is preferred that a thickness of the anodized film ranges from 5 μm to 18 μm.

It is preferred that the at least one metal base is flexible.

Also, a second aspect of the present invention provides a thin-film solar cell comprising: the substrate with an insulation layer according to the first aspect of the present invention; a back electrode formed on the insulation layer of the substrate; and a photoelectric conversion layer formed on the back electrode.

It is preferred that the thin-film solar cell further comprises a soda lime glass layer formed between the insulation layer of the substrate and the back electrode.

It is preferred that the linear thermal expansion coefficient on the front surface of the insulation layer on the side opposite to the at least one metal base is 7-12 ppm/K.

It is preferred that the back electrode made of molybdenum.

It is preferred that the photoelectric conversion layer is made of a CIGS-based semiconductor compound, and the photoelectric conversion layer has a sodium concentration of at least 10¹⁸ (atoms/cm³).

In the substrate with insulation layer according to the present invention, generation of stress due to differences in linear thermal expansion coefficient can be inhibited and peeling of the layers that constitute a thin-film solar cell can be inhibited, even when the temperature rises and falls when the layers that constitute the thin-film solar cell, such as the back electrode and photoelectric conversion layer, are formed, due to the fact that the first linear thermal expansion coefficient of the material that constitutes the insulation layer is at most 8 ppm/K, the second linear thermal expansion coefficient of the material that constitutes the metal base is at least 17 ppm/K and the third linear thermal expansion coefficient on the front surface of the insulation layer on the side opposite the metal base is 6-15 ppm/K.

### BRIEF DESCRIPTION OF THE DRAWINGS

FIG. 1 is a graph illustrating the temperature dependence of the linear thermal expansion coefficient of alumina formed by anodization, with normalized substrate length on the vertical axis and temperature on the horizontal axis.

FIG. 2 is a graph illustrating the film thickness dependence of the linear thermal expansion coefficient of an anodized film, with linear thermal expansion coefficient on the vertical axis and anodized film thickness on the horizontal axis.

FIG. 3A is a cross section schematically illustrating a substrate with insulation layer that is a first embodiment of the present invention; FIG. 3B is a cross section schematically illustrating a variation of the insulation layer of the first embodiment of the present invention.

FIG. 4 is a cross-sectional diagram schematically illustrating a solar cell submodule provided in a thin-film solar cell module according to a second embodiment of the present invention.

FIG. 5 is a graph illustrating the results of analysis of the CIGS layer by SIMS (secondary ion mass spectrometry), with sodium concentration and the secondary ion intensities of copper, gallium, selenium and indium on the vertical axes, and CIGS layer depth on the horizontal axis.

FIG. 6 is a graph illustrating the results of analysis of the CIGS layer by SIMS (secondary ion mass spectrometry), with sodium concentration and the secondary ion intensities of copper, gallium, selenium and indium on the vertical axes, and CIGS layer depth on the horizontal axis.

### DETAILED DESCRIPTION OF THE INVENTION

The substrate with insulation layer and the thin-film solar cell of the present invention will be described below based on preferred embodiments illustrated in the attached drawings.

The inventors of the present invention diligently conducted research on the peeling of layers such as the back electrode and CIGS layer (photoelectric conversion layer) that constitute the solar cell when a substrate with insulation layer on which an insulation layer is formed is used in a thin-film solar cell. The following findings were obtained as a result.

First, the inventors of the present invention studied the substrate on which the insulation layer is formed. In the study, anodization was performed on aluminum sheets of 99.5% purity while varying the duration of anodization so as to result in anodized alumina films of thicknesses 9, 14, 21, 33 and 40 μm, respectively. The anodized alumina films of each thickness were formed on the entire surface of the aluminum sheets.

The aluminum sheets on which anodized alumina films of each thickness were formed were cut into 3 cm squares and heated on a hot plate from room temperature to 500° C., and the temperature dependence of linear thermal expansion coefficient was measured for each.

The normalized substrate length was measured by measuring the distance between two points marked on the front surface of the anodized alumina film of each aluminum sheet. The temperature dependence of this normalized substrate length was measured. The linear thermal expansion coefficient can be determined based on the normalized substrate length at each temperature, and from this, the temperature dependence of linear thermal expansion coefficient can be determined.

In this case, because the distance between two points marked on the front surface of the anodized alumina film is measured, the linear thermal expansion coefficient of the outermost surface of the aluminum sheet on which the anodized alumina film was formed, that is, the surface of the anodized alumina, is obtained. As a result, the distribution of linear thermal expansion coefficient in the direction of film thickness need not be taken into consideration.

Here, the linear thermal expansion coefficient of the aluminum sheet alone is 25 ppm/K, and there is almost no temperature dependence. On the other hand, the linear thermal expansion coefficient of the anodized alumina film is 4 ppm/K, which is substantially equal to that of an amorphous alumina base.

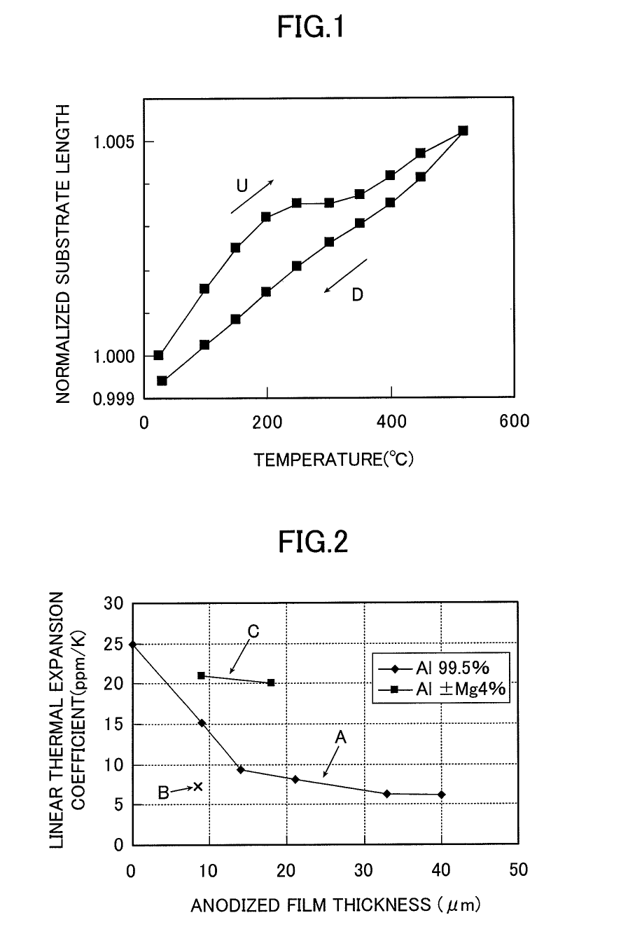

FIG. 1 shows the results of measuring the temperature dependence of the normalized substrate length (linear thermal expansion coefficient) when the thickness of the anodized alumina film was 9 μm. The arrow U in FIG. 1 indicates rising temperature, and the arrow D indicates falling temperature.

Since the difference in linear thermal expansion coefficients between aluminum and alumina is large, the change in normalized substrate length when the temperature rises and the change in normalized substrate length when the temperature falls, that is, the temperature dependence of the linear thermal expansion coefficient of the anodized alumina film (normalized substrate length), exhibits complex behavior, resulting in hysteresis as shown in FIG. 1. This is caused by plastic deformation of the aluminum sheet sandwiched by anodized alumina films.

Additionally, it was discovered that the temperature dependence of the linear thermal expansion coefficient when the temperature rises (normalized substrate length) varies depending on thermal history, while the temperature dependence of the linear thermal expansion coefficient when the temperature falls (normalized substrate length) is unaffected by thermal history and has a substantially constant value.

Furthermore, it was found that as the thickness of the anodized alumina film increased, the linear thermal expansion coefficient changed from that of aluminum (25 ppm/K) to that of alumina (4 ppm/K), as indicated by broken line A in FIG. 2. Note that in FIG. 2, the plot of anodized film thickness=0 on the horizontal axis indicates that an anodized film was not formed.

In this way, the inventors of the present invention discovered that the linear thermal expansion coefficient can be adjusted by adjusting the thickness of the anodized alumina film.

Additionally, the inventors of the present invention discovered that when a substrate on which an anodized alumina film was formed is used in a thin-film solar cell, and a back electrode and a CIGS layer as a photoelectric conversion layer are formed on this substrate, peeling occurs if the difference between linear thermal expansion coefficients is large, but peeling occurs when the temperature falls from the hot state during film deposition to room temperature, and for this reason, the linear thermal expansion coefficient when the temperature falls is important. From this fact, the required linear thermal expansion coefficient is the linear thermal expansion coefficient when the temperature is falling.

Also, on a substrate where the thickness of the aluminum sheet is 0.2 mm, anodized alumina films were similarly formed while varying the film thickness, and the linear thermal expansion coefficients of the substrates were measured. As a result, as indicated by point B in FIG. 2, the linear thermal expansion rate when the thickness of the anodized alumina film was 9 μm was 7 ppm/K. It was found that the ratio of the anodized film increases with decreasing aluminum sheet thickness, and a low linear thermal expansion coefficient is obtained when the aluminum sheet is thinner than 0.3 mm.

In addition, the linear thermal expansion coefficients of substrates were similarly measured while varying the thickness of the anodized alumina film formed on a 0.3 mm aluminum sheet containing approximately 4 mass % magnesium as an impurity. As a result, it was seen that the linear thermal expansion coefficient in this case differs greatly from the other cases, as indicated by line C in FIG. 2. This is because the slope of plastic deformation and Young's modulus of the aluminum base differs depending on impurity concentration. As indicated by line C in FIG. 2, the slope of concentration dependence of linear thermal expansion coefficient differs greatly, but a substrate of the required linear thermal expansion rate can be obtained by changing the ratio of thicknesses of the aluminum sheet and the anodized alumina film.

The substrate with insulation layer for use in solar cells of the present invention was achieved based on the above findings.

The substrate with insulation layer of the present invention will be described below.

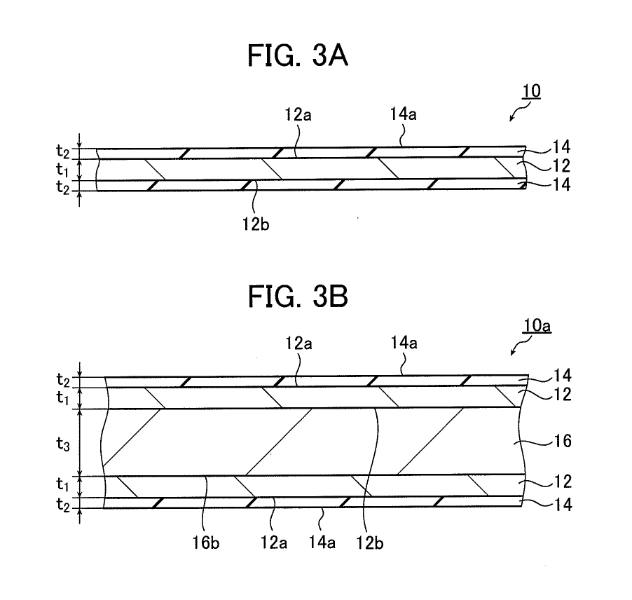

As shown in FIG. 3A, the substrate with insulation layer 10 (referred to as “substrate 10” hereinafter) has a metal base 12 and an electrically-insulating insulation layer 14.

On the substrate 10, insulation layers 14 are formed on the front surface 12a and on the back surface 12b of the metal base 12.

The substrate 10 of this embodiment is used in the substrate of a thin-film solar cell. For this reason, the shape and size of the substrate 10 are appropriately determined in accordance with the size of the applicable thin-film solar cell.

In the substrate 10, the linear thermal expansion coefficient of the material that constitutes the metal base 12 is at least 17 ppm/K. The composition of the metal base 12 is not particularly limited, provided that the linear thermal expansion coefficient is at least 17 ppm/K. As the metal base 12, aluminum or aluminum alloy, for example, may be used. In the case of aluminum, the linear thermal expansion coefficient is 25 ppm/K (±3 ppm/K). Thus, the upper limit of the linear thermal expansion coefficient of the metal base 12 is 28 ppm/K.

When aluminum or aluminum alloy, for example, is used in the metal base 12, there is a possibility of poor insulation due to intermetallic compounds, and if there are a lot of intermetallic compounds, this possibility increases. For this reason, the aluminum or aluminum alloy preferably does not contain extraneous intermetallic compounds. Specifically, aluminum with a purity of at least 99 mass % which contains few impurities is preferred. For example, aluminum with a purity of 99.99 mass %, aluminum with a purity of 99.96 mass %, aluminum with a purity of 99.9 mass %, aluminum with a purity of 99.85 mass %, aluminum with a purity of 99.7 mass % and aluminum with a purity of 99.5 mass % are preferred. Also, aluminum alloys to which elements that tend not to form intermetallic compounds have been added may be used. An example is aluminum alloy to which 2.0-7.0 mass % magnesium has been added to aluminum with a purity of 99.9%. Other than magnesium, elements with a high solid solubility limit, such as copper and silicon, may be added.

Because the thickness of the metal base 12 affects flexibility, it is preferably thin, but in a range such that it does not excessively lack hardness.

In the substrate 10 of this embodiment, the thickness of the metal base 12 is, for example, 5-150 μm, preferably 10-100 μm. It is more preferably 20-50 μm.

Also, the surface roughness of the metal base 12 is, for example, 1 μm or less as arithmetic mean roughness Ra. It is preferably 0.5 μm or less, more preferably 0.1 μm or less.

The insulation layer 14 is for insulation and for preventing damage by mechanical impact during handling. The linear thermal expansion coefficient of the material that constitutes the insulation layer 14 is at most 8 ppm/K.

On top of the front surface 14a of the insulation layer 14, a soda lime glass layer, back electrode, photoelectric conversion layer and so forth which constitute the thin-film solar cell are formed.

The composition of the insulation layer 14 is not particularly limited, provided that the linear thermal expansion coefficient is at most 8 ppm/K. As the insulation layer 14, alumina, for example, may be used. This alumina is, for example, anodized alumina obtained by anodizing the metal base 12 made of aluminum or aluminum alloy. The linear thermal expansion coefficient of this anodized alumina is 3-8 ppm/K. For this reason, the linear thermal expansion coefficient of the insulation layer 14 is preferably 3-8 ppm/K.

The thickness of the insulation layer 14 is preferably at least 5 μm in order to assure insulation properties. On the other hand, the thickness of the insulation layer 14 is preferably at most 18 μm in order to assure flexibility of the substrate 10 as a whole.

The front surface of the insulation layer 14 has a surface roughness in terms of, for example, arithmetic mean roughness Ra, of 1 μm or less, preferably 0.5 μm or less, and more preferably 0.1 μm or less.

In the substrate 10, the linear thermal expansion coefficient of the front surface 14a of the insulation layer 14 on the side opposite the metal base 12, rather than the interface between the metal base 12 and the insulation layer 14, is 6-15 ppm/K. More preferably, the linear thermal expansion coefficient of the front surface 14a of the insulation layer 14 is 7-12 ppm/K.

If the linear thermal expansion coefficient of the front surface 14a of the insulation layer 14 is less than 6 ppm/K, peeling may occur in any of the layers that constitute the thin-film solar cell, such as the soda lime glass layer, back electrode, CIGS layer (photoelectric conversion layer), CdS buffer layer, ZnO layer and collector electrode formed on top of the front surface 14a of the insulation layer 14.

If the linear thermal expansion coefficient of the front surface 14a of the insulation layer 14 is greater than 15 ppm/K, peeling may occur in any of the aforementioned layers that constitute the thin-film solar cell, such as the soda lime glass layer, back electrode, CIGS layer (photoelectric conversion layer), CdS buffer layer, ZnO layer and collector electrode.

As described above, the linear thermal expansion coefficient of the front surface 14a of the insulation layer 14 is 6-15 ppm/K, more preferably 7-12 ppm/K. If the insulation layer 14 is an anodized film of aluminum, the insulation layer material alone has a typical value of 5 ppm/K, and at most 8 ppm/K. In this case in the substrate 10, the linear thermal expansion coefficient of the front surface 14a of the insulation layer 14 may be 6 ppm/K, but if use as a flexible substrate is taken into consideration, the metal base 12 must be a thin film. For this reason, it is preferred that the linear thermal expansion coefficient of the front surface 14a of the insulation layer 14 is the opposite of the linear thermal expansion coefficient of the insulation material alone. That is, it is preferred that the linear thermal expansion coefficient of the front surface 14a of the insulation layer 14 is large. When attempting to make the metal base 12 thinner, it is preferred that the linear thermal expansion coefficient of the front surface 14a of the insulation layer 14 is greater than 12 ppm/K.

In the substrate 10, the linear thermal expansion coefficient of the front surface 14a of the insulation layer 14 can be set to 6-15 ppm/K by taking advantage of the fact that, as shown in FIG. 2, the linear thermal expansion coefficient varies depending on the thickness of the insulation layer 14 (refer to broken line A in FIG. 2), the thickness of the metal base 12 (refer to point B in FIG. 2), and the composition (refer to line C of FIG. 2). Thus, the linear thermal expansion coefficient of the front surface 14a of the insulation layer 14 can be set to 6-15 ppm/K by varying the ratio of thickness t₁ of the metal base 12 and thickness t₂ of the insulation layer 14.

Note that the film thickness dependence of the linear thermal expansion coefficient differs depending on the composition of the metal base and the composition of the insulation layer. Therefore, for the case of the substrate 10 shown in FIG. 3A, it is preferred that the substrate is constructed after determining the ratio of thickness t₁ of the metal base 12 and thickness t₂ of the insulation layer 14, based on advance examination of the film thickness dependence of the linear thermal expansion coefficient depending on various compositions of the metal base and various compositions of the insulation layer.

In the substrate 10 of this embodiment, insulation layers 14 are formed on both surfaces of the metal base 12, but the present invention is not limited to this configuration, and may be constructed by providing an insulation layer 14 only on the front surface 12a of the metal base 12, provided that the linear thermal expansion coefficient of the front surface 14a of the insulation layer 14 is 6-15 ppm/K.

Also, in the substrate 10 of this embodiment, the metal base 12 has a single-layer structure, but the present invention is not limited thereto. For example, it may be constructed such that a second metal base 16 is provided on the back surface 12b of the metal base 12, and the metal base 12 is provided on the back surface 16b of the second metal base 16, and the insulation layer 14 is provided on the front surface 12a of the metal base 12, as in the substrate 10a shown in FIG. 3B. In this case, the linear thermal expansion coefficient of the second metal base 16 is at least 17 ppm/K, similar to the metal base 12. Moreover, in the five-layer substrate 10a, the linear thermal expansion coefficient of the front surface 14a of the insulation layer 14 must be 6-15 ppm/K.

In the case of a multilayer metal base as in substrate 10a, the substrate 10a is constructed after determining the ratio of thickness t₁ of the metal base 12, thickness t₃ of the second metal base 16, thickness of the multilayer metal and thickness t₂ of the insulation layer 14, based on advance examination of the film thickness dependence of the linear thermal expansion coefficient of the metal base that constitutes the multilayer structure and the film thickness dependence of the linear thermal expansion coefficient depending on various compositions of the insulation layers.

Note that the substrate 10a, similar to the substrate 10, may also be configured such that the metal base 12 and insulation layer 14 are not provided on the back surface 16b side of the second metal base 16, as long as the linear thermal expansion coefficient of the front surface 14a of the insulation layer 14 is 6-15 ppm/K.

In this embodiment, for the substrate 10, a metal base 12, of which the constituent material has a linear thermal expansion coefficient of at least 17 ppm/K, and an insulation layer 14, of which the constituent material has a linear thermal expansion coefficient of at most 8 ppm/K, are laminated, and the linear thermal expansion coefficient on the front surface 14a of the insulation layer 14 is 6-15 ppm/K. As a result, when forming the layers that constitute the thin-film solar cell, such as the soda lime glass layer, back electrode, CIGS layer (photoelectric conversion layer), CdS buffer layer, ZnO layer and collector electrode, generation of stress due to differences in the linear thermal expansion coefficients of the formed layers is suppressed even when the temperature rises or falls.

Also, the same effects as those of the substrate 10 can be obtained in the substrate 10a as well. Additionally, the same effects as those of the substrate 10 can be obtained even if the substrate 10 has a structure in which an insulation layer 14 is provided only on the front surface 12a of the metal base 12, and even when the substrate 10a has a structure in which no metal base 12 and no insulation layer 14 are provided on the back surface 16b side of the second metal base 16.

Next, the production method of the substrate 10 of this embodiment will be described.

When producing the substrate 10, the film thickness dependence of the linear thermal expansion coefficient depending on the compositions of the metal base and the compositions of the insulation layer are examined in advance, and the ratio of thickness of the metal base 12 and thickness of the insulation layer 14 are determined.

Then, a metal base 12 having the determined composition and thickness is prepared.

Then, if an anodized film is to be used as the insulation layer 14, the anodization treatment conditions are set in accordance with the thickness of the formed insulation layer 14, and the anodization treatment described in detail below is performed under these conditions. As a result, an insulation layer 14 of the specified thickness is obtained on both surfaces of the substrate 10. The substrate 10 can be thus produced.

Also, the formation method of the insulation layer 14 is not limited to anodization treatment. For example, the insulation layer 14 may be formed with the specified composition and thickness by sputtering or CVD.

Anodization treatment will be described in detail below.

When the insulation layer 14 is formed by anodization treatment, it can be formed by immersing the metal base 12 as the anode in an electrolytic solution together with a cathode, and applying voltage between the anode and the cathode. In this case, on the metal base 12, regions where the insulation layer 14 is not to be formed must be insulated by masking with a protective sheet (not shown) so that they do not come in contact with the electrolytic solution. That is, the end surfaces of the back surface 12b of the metal base 12 must be insulated using a protective sheet (not shown).

Where necessary, the front surface of the metal base 12 may be subjected to cleaning and polishing/smoothing processes prior to anodization.

Carbon or aluminum or the like is used for the cathode in anodization. As the electrolyte, an acidic electrolytic solution containing one or more kinds of acids such as sulfuric acid, phosphoric acid, chromic acid, oxalic acid, sulfamic acid, benzenesulfonic acid and amidosulfonic acid is used. The anodization conditions vary with the type of electrolyte used and are not particularly limited. As an example, appropriate anodization conditions are an electrolyte concentration of 1-80 mass %, a solution temperature of 5-70° C., a current density of 0.005-0.60 A/cm², a voltage of 1-200 V and an electrolysis time of 3-500 minutes. The electrolyte is preferably sulfuric acid, phosphoric acid, oxalic acid or a mixture thereof. When an electrolyte as described above is used, an electrolyte concentration of 4-30 mass %, a solution temperature of 10-30° C., a current density of 0.002-0.30 A/cm² and a voltage of 20-100 V are preferred.

When anodization treatment is performed, an oxidation reaction proceeds substantially in the vertical direction from the front surface 12a and back surface 12b of the aluminum base 12 to form an anodized film on the front surface 12a and back surface 12b of the aluminum base 12. In cases where any of the above electrolytic solutions is used, the anodized film is of a porous type in which a large number of fine columns in the shape of a substantially regular hexagon as seen from above are arranged without gaps, and a micropore having a rounded bottom is formed at the core of each fine column, the bottom of each fine column having a barrier layer (typically 0.02-0.1 μm thick).

Compared to non-porous-structure aluminum oxide single film, this type of porous-structure anodized film has a lower Young's modulus, higher bending resistance, and higher resistance to cracking due to a difference in thermal expansion when heated.

Note that a dense anodized film (non-porous aluminum oxide single film), rather than an anodized film in which porous fine columns are arranged, is obtained by electrolytic treatment in a neutral electrolytic solution such as boric acid without using an acidic electrolytic solution. An anodized film in which the thickness of the barrier layer has been increased by pore filling may be formed by again performing electrolysis treatment with a neutral electrolytic solution after the porous anodized film is produced with an acidic electrolytic solution. The insulation properties of the film may be increased by increasing the thickness of the barrier layer.

In cases where it is desired to increase the insulation properties of the insulation layer 14 formed by anodization, pore sealing treatment is performed in a boric acid solution.

Electrochemical methods and chemical methods of pore sealing are known, but an electrochemical method wherein aluminum and aluminum alloy are anodized (anodic treatment) is particularly preferred.

A preferred electrochemical pore sealing method is that in which DC current is applied to aluminum or an alloy thereof as the anode. Boric acid aqueous solution is preferred as the electrolytic solution, and an aqueous solution obtained by adding a borate containing sodium to boric acid aqueous solution is even more preferred. Examples of borates include disodium octaborate, sodium tetraphenylborate, sodium tetrafluoroborate, sodium peroxoborate, sodium tetraborate, sodium metaborate and so forth. The borates may be procured as anhydrides or hydrates.

A particularly preferred electrolytic solution used in pore sealing is an aqueous solution obtained by adding 0.01-0.5 mol/L sodium tetraborate to 0.1-2 mol/L boric acid aqueous solution. It is preferred that aluminum ions are dissolved in an amount of 0-0.1 mol/L. Aluminum ions may be dissolved chemically or electrochemically by pore sealing treatment in an electrolytic solution, but a particularly preferred method is electrolysis after adding aluminum borate in advance. Also, trace elements contained in the aluminum alloy may be dissolved.

Preferred pore sealing conditions are a solution temperature of 10-55° C. (more preferably 10-30° C.), a current density of 0.01-5 A/dm² (more preferably 0.1-3 A/dm²) and an electrolytic treatment time of 0.1-10 minutes (more preferably 1-5 minutes).

The current used may be AC, DC or overlapping AC current, and the method of applying current may be by constant application from the start of electrolysis or by gradual increase, but the use of DC is particularly preferred. The method of applying current may be either by constant voltage or constant current.

The voltage between the substrate and the opposing electrode in this case is preferably 100-1000 V, but varies depending on the composition of the electrolytic solution, solution temperature, flow rate at the aluminum interface, power supply waveform, distance between substrate and opposing electrode, electrolysis time and so forth.

The flow and the method of providing flow of the electrolytic solution on the substrate surface and the method of concentration control of the electrolyte tank, electrodes and electrolytic solution may be known methods of anodization treatment and pore sealing according to the anodization treatment described above. The film thickness when anodization is performed in a boric acid aqueous solution containing a sodium borate is preferably at least 100 nm, more preferably at least 300 nm. The upper limit is the film thickness of the porous anodized film. As a result, it can be used in a substrate of thin-film solar cells, in which high-temperature strength is a requirement and flexibility is a plus.

A preferred chemical method that can be used is to make a structure in which pores and/or voids are filled with a silicon oxide substance after anodization treatment. Filling with a silicon oxide substance may be performed by coating with a solution containing a compound having Si—O bonds, or by immersing for 1-30 seconds in sodium silicate aqueous solution (aqueous solution containing 1-5 mass % No. 1 sodium silicate or No. 3 sodium silicate, at 20-70° C.) and then washing with water, drying, and firing for 1-60 minutes at 200-600° C.

A preferred chemical method other than the above-described sodium silicate aqueous solution is to perform pore sealing treatment by immersing for 1-60 seconds at 20-70° C. in a solution having a concentration of 1-5 mass % containing sodium fluorosilicate and/or sodium dihydrogen phosphate alone or a mixture with a mixing ratio of 5:1 to 1:5 by weight.

Anodization treatment can be performed using, for example, a known anodization apparatus of so-called roll-to-roll process type.

For this reason, the substrate 10 of this embodiment may be produced by the roll-to-roll process, provided that the metal base 12 can be conveyed by the roll-to-roll process. Thus, it can be produced at low cost.

When producing the substrate 10a as shown in FIG. 3B, in the case of a multilayer metal base, the ratio of thickness t₁ of the metal base 12, thickness t₃ of the second metal base 16, thickness of the multilayer metal and thickness t₂ of the insulation layer 14 is determined, based on advance examination of the film thickness dependence of the linear thermal expansion coefficient of the metal base that constitutes the multilayer structure and the film thickness dependence of the linear thermal expansion coefficient depending on various compositions of the insulation layers.

Then, metal bases having the respective compositions and thicknesses are prepared.

Then, the front surfaces of the metal bases are cleaned, for example, and they are integrated by pressurizing and bonding by rolling or the like. Multilayer metal bases are thus obtained.

Note that pressurizing and bonding by rolling or the like is the preferred method of forming the multilayer metal base in terms of cost and mass producibility. However, the multilayer metal base may also be formed by vapor-phase methods such as vapor deposition or sputtering, or by plating.

The method of forming the insulation layer 14 is the same as for a single-layer metal base, and therefore a detailed description thereof is omitted. The substrate 10a shown in FIG. 3B may be thus obtained.

Also, in the substrate 10a, similar to the substrate 10, it may be produced by the roll-to-roll process, provided that the metal base 12 can be transported by the roll-to-roll process, in the state where the metal base 12 and the second metal base 16 have been integrated. Thus, it can be produced at low cost.

Next, a second embodiment of the invention will be described.

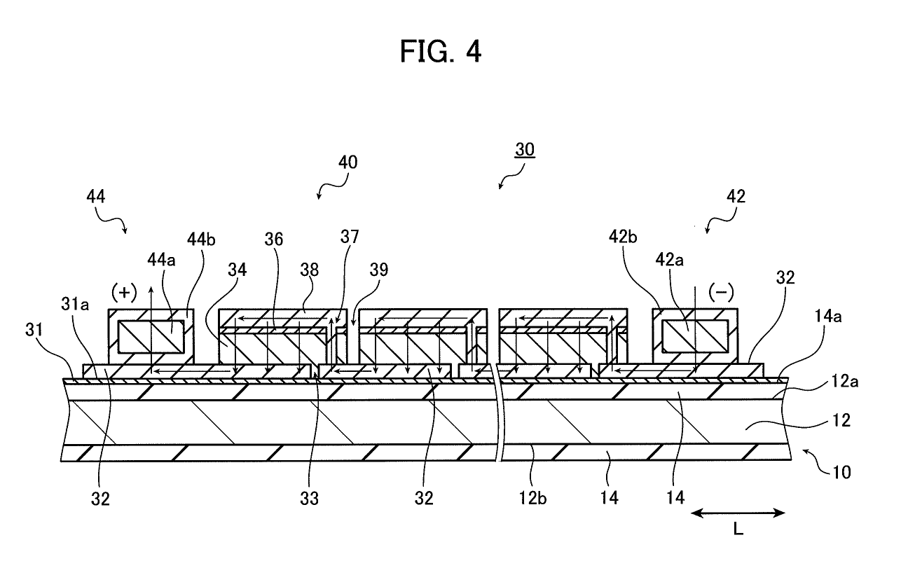

FIG. 4 is a cross-sectional diagram schematically illustrating a solar cell submodule provided in a thin-film solar cell module according to a second embodiment of the present invention.

Note that in this embodiment, the same components as those of the substrate 10 according to the first embodiment illustrated in FIG. 1 will be given the same reference numerals, and a detailed description thereof will be omitted.

The thin-film solar module of this embodiment uses the substrate 10 of the first embodiment as the substrate, and, solar cell submodules 30 are formed on this substrate 10.

The solar cell submodule 30 has a plurality of photoelectric conversion elements 40, a first conductive member 42 and a second conductive member 44.

The photoelectric conversion elements 40 function as solar cells, and are constructed from, for example, a soda lime glass layer 31, back electrode 32, photoelectric conversion layer 34, buffer layer 36 and transparent electrode 38.

The soda lime glass layer 31 is formed on the front surface 14a of the insulation layer 14. On the front surface 31a of the soda lime glass layer 31, the back electrode 32, photoelectric conversion layer 34, buffer layer 36 and transparent electrode 38 are laminated in sequence.

The back electrodes 32 are formed on the front surface 31a of the soda lime glass layer 31, with separation grooves (P1) 33 provided for separation from adjacent back electrodes 32. The photoelectric conversion layer 34 is formed on the back electrodes 32 so as to fill the separation grooves (P1) 33. The buffer layer 36 is formed on the front surface of the photoelectric conversion layer 34. The photoelectric conversion layers 34 and the buffer layers 36 are separated from adjacent photoelectric conversion layers 34 and adjacent buffer layers 36 by grooves (P2) 37 which reach the back electrodes 32. The grooves (P2) 37 are formed in different positions from those of the separation grooves (P1) 33 that separate the back electrodes 32.

The transparent electrode 38 is formed on the surface of the buffer layer 36 so as to fill the grooves (P2) 37.

Opening grooves (P3) 39 are formed so as to reach the back electrodes 32 by penetrating through the transparent electrode 38, the buffer layer 36, and the photoelectric conversion layer 34. The photoelectric conversion elements 40 are connected in series in the longitudinal direction L of the substrate 10 via the back electrodes 32 and the transparent electrodes 38.

The photoelectric conversion elements 40 of this embodiment are so-called integrated photoelectric conversion elements (solar cells), and have a configuration such that, for example, the back electrode 32 is a molybdenum electrode, the photoelectric conversion layer 34 is formed of a semiconductor compound having a photoelectric conversion function such as, for example, a CIGS layer, the buffer layer 36 is formed of CdS, and the transparent electrode 38 is formed of ZnO.

Note that the photoelectric conversion elements 40 are formed so as to extend in the width direction perpendicular to the longitudinal direction L of the substrate 10. Therefore, the back electrodes 32 also extend in the width direction of the substrate 10.

As illustrated in FIG. 4, the first conductive member 42 is connected to the rightmost back electrode 32. The first conductive member 42 is provided to collect the output from a negative electrode to be described later. Although a photoelectric conversion element 40 is formed on the rightmost back electrode 32, that photoelectric conversion element 40 is removed by, say, laser scribing or mechanical scribing to expose the back electrode 32.

The first conductive member 42 is, for example, a member in the shape of an elongated strip which extends substantially linearly in the width direction of the substrate 10 and is connected to the rightmost back electrode 32. As shown in FIG. 4, the first conductive member 42 has, for example, a copper ribbon 42a covered with a coating material 42b made of an alloy of indium and copper. The first conductive member 42 is connected to the back electrode 32 by, for example, ultrasonic soldering.

A second conductive member 44 is provided to collect the output from the positive electrode to be described later. Like the first conductive member 42, the second conductive member 44 is a long strip extending substantially linearly in the width direction of the substrate 10, connected to the leftmost back electrode 32. Although a photoelectric conversion element 40 is formed on the leftmost back electrode 32, that photoelectric conversion element 40 is removed by, say, laser scribing or mechanical scribing to expose the back electrode 32.

The second conductive member 44 is composed similarly to the first conductive member 42 and has, for example, a copper ribbon 44a covered with a coating material 44b made of an alloy of indium and copper.

The first conductive member 42 and the second conductive member 44 may be formed of a tin-plated copper ribbon. Furthermore, the method of connection of the first conductive member 42 and the second conductive member 44 is not limited to ultrasonic soldering, and they may be connected by such means as, for example, a conductive adhesive or conductive tape.

The photoelectric conversion elements 40 of this embodiment may be fabricated by any of known methods used to fabricate CIGS solar cells.

The separation grooves (P1) 33 of the back electrodes 32, the grooves (P2) 37 reaching the back electrodes 32, and the opening grooves (P3) 39 reaching the back electrodes 32 may be formed by laser scribing or mechanical scribing.

In the solar cell submodule 30, light impinging on the photoelectric conversion elements 40 from the side bearing the transparent electrodes 38 passes through the transparent electrodes 38 and the buffer layers 36 and causes the photoelectric conversion layers 34 to generate electromotive force, thus producing a current that flows, for example, from the transparent electrodes 38 to the back electrodes 32. Note that the arrows shown in FIG. 4 indicate the direction of the current, and the direction in which electrons move is opposite to that of current. Therefore, in the photoelectric converters 48, the leftmost back electrode 32 in FIG. 4 has a positive polarity (plus polarity) and the rightmost back electrode 32 has a negative polarity (minus polarity).

In this embodiment, electromotive force generated in the solar cell submodule 30 can be output from the solar cell submodule 30 through the first conductive member 42 and the second conductive member 44.

Also, in this embodiment, the first conductive member 42 has a negative polarity, and the second conductive member 44 has a positive polarity. The polarities of the first conductive member 42 and the second conductive member 44 may be reversed; their polarities may vary according to the configuration of the photoelectric conversion elements 40, the configuration of the solar cell submodule 30, and the like.

In this embodiment, the photoelectric conversion elements 40 are formed so as to be connected in series in the longitudinal direction L of the substrate 10 through the back electrodes 32 and the transparent electrodes 38, but the present invention is not limited thereto. For example, the photoelectric conversion elements 40 may be formed so as to be connected in series in the width direction through the back electrodes 32 and the transparent electrodes 38.

The back electrodes 32 and the transparent electrodes 38 of the photoelectric conversion elements 40 are both provided to collect current generated by the photoelectric conversion layers 34. Both the back electrodes 32 and the transparent electrodes 38 are each made of a conductive material. The transparent electrodes 38 must be have translucency.

The soda lime glass layer 31 is for diffusing an alkali metal element, for example, Na in the photoelectric conversion layer 34 (CIGS layer). This is because it has been reported that photoelectric conversion efficiency is increased when an alkali metal element, for example, Na is diffused in the photoelectric conversion layer 34. In the photoelectric conversion elements 40, an alkali metal can be diffused in the photoelectric conversion layer 34 and photoelectric conversion efficiency can be increased by providing a soda lime glass layer 31.

In this embodiment, it is not limited to a soda lime glass layer 31, provided that it can diffuse an alkali metal element in the photoelectric conversion layer 34.

For example, a layer containing an alkali metal element may be formed by vapor deposition or sputtering on top of the back electrodes 32. Or, an alkali layer composed of Na₂S or the like may be formed on the back electrode by dipping, for example. Also, a layer may be formed on the back electrodes 32 by forming a precursor containing indium (In), copper (Cu) and gallium (Ga) metal elements, and then applying an aqueous solution containing sodium molybdate, for example, to the precursor.

Instead of the soda lime glass layer 31, a layer containing one or two or more alkali metal compounds such as Na₂S, Na₂Se, NaCl, NaF and sodium molybdate salt may be provided inside the back electrodes 32.

Note that the solar cell submodule 30 of this embodiment may also be configured such that the back electrodes 32 are formed on the front surface 14a of the insulation layer 14, rather than a soda lime glass layer 31 being provided.

The back electrodes 32 are formed, for example, of molybdenum (Mo), chromium (Cr) or tungsten (W), or a combination thereof. The back electrodes 32 may have a single-layer structure or a laminated structure such as a two-layer structure. The back electrodes 32 are preferably made of molybdenum.

The back electrodes 32 have a thickness of 100 nm or more, preferably 0.45-1.0 μm.

The back electrodes 32 may be formed by any vapor-phase film deposition method such as electron beam vapor deposition or sputtering.

The transparent electrodes 38 are formed, for example, of ZnO doped with aluminum, boron, gallium, antimony, etc., ITO (indium tin oxide), SnO₂, or a combination thereof. The transparent electrodes 38 may have a single-layer structure or a laminated structure such as a two-layer structure. The thickness of the transparent electrodes 38, which is not specifically limited, is preferably 0.3-1 μm.

The method of forming the transparent electrodes 38 is not particularly limited; they may be formed by coating techniques or vapor-phase deposition techniques such as electron beam vapor deposition and sputtering.

The buffer layers 36 are provided to protect the photoelectric conversion layers 34 when forming the transparent electrodes 38 and to allow the light impinging on the transparent electrodes 38 to enter the photoelectric conversion layers 34.

The buffer layers 36 are made of, for example, CdS, ZnS, ZnO, ZnMgO or ZnS (O, OH) or a combination thereof.

The buffer layers 36 preferably have a thickness of 0.03-0.1 μm. The buffer layers 36 are formed by, for example, chemical bath deposition (CBD) method.

The photoelectric conversion layer 34 has a photoelectric conversion function, such that it generates current by absorbing light that has reached it through the transparent electrode 38 and the buffer layer 36. In this embodiment, the photoelectric conversion layers 34 are not specifically limited in configuration; they may be formed, for example, of a compound semiconductor having at least one kind of chalcopyrite structure. The photoelectric conversion layers 34 may be formed of at least one kind of compound semiconductor composed of a group Ib element, a group IIIb element, and a group VIb element.

For high optical absorbance and high photoelectric conversion efficiency, the photoelectric conversion layers 34 are preferably formed of at least one kind of compound semiconductor composed of at least one kind of group Ib element selected from the group consisting of Cu and Ag, at least one kind of group IIIb element selected from the group consisting of Al, Ga, and In, and at least one kind of group VIb element selected from the group consisting of S, Se, and Te. Examples of the compound semiconductor include CuAlS₂, CuGaS₂, CuInS₂ CuAlSe₂, CuGaSe₂, CuInSe₂ (CIS), AgAlS₂, AgGaS₂, AgInS₂, AgAlSe₂, AgGaSe₂, AgInSe₂, AgAlTe₂, AgGaTe₂, AgInTe₂, Cu(In₁₋ₓGaₓ)Se₂ (CIGS), Cu(In₁₋ₓAlₓ)Se₂, Cu(In₁₋ₓGaₓ) (S, Se)₂, Ag(In₁₋ₓGaₓ)Se₂ and Ag(In₁₋ₓGaₓ) (S, Se)₂.

The photoelectric conversion layers 34 preferably contain CuInSe₂(CIS) and/or Cu(In, Ga)Se₂ (CIGS), which is obtained by solid-dissolving (solute) Ga in the former. CIS and CIGS are semiconductors each having a chalcopyrite crystal structure, and reportedly have high optical absorbance and high photoelectric conversion efficiency. Further, they have little deterioration of efficiency under exposure to light and exhibit excellent durability.

The photoelectric conversion layer 34 contains impurities for obtaining the desired semiconductor conductivity type. Impurities may be added to the photoelectric conversion layer 34 by diffusion from adjacent layers and/or direct doping into the photoelectric conversion layer 34. There may be a concentration distribution of constituent elements of group I-III-VI semiconductors and/or impurities in the photoelectric conversion layer 34, which may contain a plurality of layer regions formed of materials having different semiconductor properties such as n-type, p-type, and i-type.

For example, in a CIGS semiconductor, when provided with a distribution in the amount of gallium in the direction of thickness in the photoelectric conversion layer 34, the band gap width, carrier mobility, etc. can be controlled, and thus high photoelectric conversion efficiency is achieved.

The photoelectric conversion layers 34 may contain one or two or more kinds of semiconductors other than group I-III-VI semiconductors. Such semiconductors other than group I-III-VI semiconductors include a semiconductor formed of a group IVb element such as Si (group IV semiconductor), a semiconductor formed of a group IIIb element and a group Vb element (group III-V semiconductor) such as GaAs, and a semiconductor formed of a group IIb element and a group VIb (group II-VI semiconductor) such as CdTe. The photoelectric conversion layers 34 may contain any other component than a semiconductor and impurities used to obtain a desired conductivity type, provided that no detrimental effects are thereby produced on the properties.

The photoelectric conversion layers 34 may contain a group I-III-VI semiconductor in any amount as deemed appropriate. The ratio of group I-III-VI semiconductor contained in the photoelectric conversion layers 34 is preferably 75 mass % or more and, more preferably, 95 mass % or more and, most preferably, 99 mass % or more.

When the photoelectric conversion layer 34 of this embodiment is a CIGS layer, the CIGS layer may be formed by such known film deposition methods as 1) multi-source co-evaporation method, 2) selenization method, 3) sputtering method, 4) hybrid sputtering method, and 5) mechanochemical processing method.

1) Known multi-source co-evaporation methods include: the three-stage method (J. R. Tuttle et al., Mat. Res. Soc. Symp. Proc., Vol. 426 (1966), p. 143, etc.), and the co-evaporation method of the EC group (L. Stolt et al., Proc. 13th ECPVSEC (1995, Nice), 1451, etc.).

According to the former three-phase method, firstly, In, Ga and Se are simultaneously evaporated under high vacuum at a substrate temperature of 300° C., which is then increased to 500° C. to 560° C. to simultaneously vapor-deposit Cu and Se, whereupon In, Ga and Se are further simultaneously evaporated. The latter simultaneous evaporation method by EC group is a method which involves evaporating copper-excess CIGS in the earlier stage of evaporation, and evaporating indium-excess CIGS in the latter half of the stage.

Improvements have been made on the foregoing methods to improve the crystallinity of CIGS films, and the following methods are known:

a) Method using ionized Ga (H. Miyazaki et al., Phys. Stat. Sol. (a), Vol. 203 (2006), p. 2603, etc.);
b) Method using cracked selenium (a pre-printed collection of presentations given at the 68th Academic Lecture by the Japan Society of Applied Physics) (autumn, 2007, Hokkaido Institute of Technology), 7P-L-6, etc.);
c) Method using radicalized selenium (a pre-printed collection of presentations given at the 54th Academic Lecture by the Japan Society of Applied Physics) (spring, 2007, Aoyama Gakuin Univ.), 29P-ZW-10, etc.); and
d) Method using a light excitation process (a pre-printed collection of presentations given at the 54th Academic Lecture by the Japan Society of Applied Physics) (spring, 2007, Aoyama Gakuin Univ.), 29P-ZW-14, etc.).

2) The selenization method is also called the two-stage method, whereby, firstly, a metal precursor formed of a laminated film such as a copper layer/indium layer, a (copper-gallium) layer/indium layer or the like is formed by sputter deposition, vapor deposition, or electrodeposition, and the film thus formed is heated in selenium vapor or hydrogen selenide to a temperature of 450° C. to 550° C. to produce a selenide such as Cu(In₁₋ₓGaₓ)Se₂ by thermal diffusion reaction. This method is called vapor-phase selenization. Another exemplary method is solid-phase selenization in which solid-phase selenium is deposited on a metal precursor film and selenized by a solid-phase diffusion reaction using the solid-phase selenium as the selenium source.

The selenization method may be implemented in several ways: selenium is previously mixed in a given ratio into the metal precursor film to avoid abrupt volume expansion that might take place in the selenization process (T. Nakada et al., Solar Energy Materials and Solar Cells 35 (1994), 204-214, etc.); or selenium is sandwiched between thin metal films (e.g., as in copper layer/indium layer/selenium layer . . . copper layer/indium layer/selenium layer) to form a multiple-layer precursor film (T. Nakada et al., Proc. of 10th European Photovoltaic Solar Energy Conference (1991), 887-890, etc.).

An exemplary method of forming a graded band gap CIGS film is a method which involves first depositing a copper-gallium (Cu—Ga) alloy film, depositing an indium film thereon and selenizing with a gallium concentration gradient in the film thickness direction making use of natural thermal diffusion (K. Kushiya et al., Tech. Digest 9th Photovoltaic Science and Engineering Conf. Miyazaki, 1996 (Intn. PVSEC-9, Tokyo, 1996), p. 149, etc.).

3) Known sputtering techniques include: a technique using CuInSe₂ polycrystal as a target, a technique two-source sputtering using H₂Se/Ar mixed gas as sputter gas with Cu₂Se and In₂Se₃ as targets (J. H. Ermer et al., Proc. 18th IEEE Photovoltaic Specialists Conf. (1985), 1655-1658, etc.) and, a technique called three-source sputtering whereby a copper target, an indium target and a selenium or CuSe target are sputtered in argon gas (T. Nakada et al., Jpn. J. Appl. Phys. 32 (1993), L1169-L1172, etc.).

4) Exemplary known methods for hybrid sputtering include one in which copper and indium metals are subjected to DC sputtering in the sputtering method described above, while only selenium is vapor-deposited (T. Nakada et al., Jpn. Appl. Phys. 34 (1995), 4715-4721, etc.).

5) An exemplary method for mechanochemical processing includes a method in which a material selected according to the CIGS composition is placed in a planetary ball mill container and mixed by mechanical energy to obtain pulverized CIGS, which is then applied to a substrate by screen printing and annealed to obtain a CIGS film (T. Wada et al., Phys. Stat. Sol. (a), Vol. 203 (2006), p. 2593, etc.).

Other exemplary methods for forming CIGS films include screen printing, close-spaced sublimation, MOCVD and spraying (wet deposition). For example, crystals with a desired composition can be obtained by a method which involves forming a fine particle film containing a group Ib element, a group IIIb element and a group VIb element on a substrate by, for example, screen printing (wet deposition) or spraying (wet deposition) and subjecting the fine particle film to pyrolysis treatment (which may be a pyrolysis treatment carried out under a group VIb element atmosphere) (JP 9-74065 A, JP 9-74213 A, etc.).

Next, the method of producing the solar cell submodule 30 according to this embodiment will be described.

First, the substrate 10 is prepared. The method of producing the substrate 10 is the same as in to the first embodiment, and therefore a detailed description thereof is omitted.

Then, a soda lime glass layer 31 is formed on the front surface 14a of the insulation layer 14 of the substrate 10 by RF sputtering using a film deposition apparatus.

Then, a molybdenum film serving as the back electrodes 32 is formed on the front surface 31a of the soda lime glass layer 31 by DC sputtering using a film deposition apparatus.

Then, for example, laser scribing is used to scribe the molybdenum film at a first predetermined position to form the separation grooves (P1) 33 extending in the width direction of the substrate 10. The back electrodes 32 separated from each other by the separation grooves (P1) 33 are thus formed.

Then, for example, a CIGS layer is formed by any of the film deposition methods described above using a film deposition apparatus, so as result in a photoelectric conversion layer 34 (p-type semiconductor layer) which covers the back electrodes 32 and fills in the separation grooves (P1) 33.

Then, a CdS layer (n-type semiconductor layer) serving as the buffer layer 36 is formed on the CIGS layer by, for example, chemical bath deposition (CBD) method. A p-n junction semiconductor layer is thus formed.

Then, laser scribing is used to scribe a second position, which differs from the first position of the separation grooves (P1) 33, so as to form grooves (P2) 37 which extend in the width direction of the substrate 10 and reach the back electrodes 32.

Then, a layer of ZnO doped with, for example, aluminum, boron, gallium, antimony or the like which serves as the transparent electrodes 38 is formed on the buffer layer 36 by sputtering or coating using a film deposition apparatus so as to fill the grooves (P2) 37.

Then, laser scribing is used to scribe a third position, which differs from the first position of the separation grooves (P1) 33 and the second position of the grooves (P2) 37, so as to form opening grooves (P3) 39 which extend in the width direction of the substrate 10 and reach the back electrodes 32.

Then, the photoelectric conversion elements 40 formed on the rightmost and leftmost back electrodes 32 in the longitudinal direction L of the substrate 10 are removed by, for example, laser scribing or mechanical scribing, to expose the back electrodes 32. Then, the first conductive member 42 and the second conductive member 44 are connected by, for example, ultrasonic soldering onto the rightmost and leftmost back electrodes 32, respectively.

The solar cell submodule 30 in which a plurality of photoelectric conversion elements 40 are electrically connected in series can be thus produced, as shown in FIG. 4.

Then, a bond/seal layer (not shown), a water vapor barrier layer (not shown) and a surface protection layer (not shown) are arranged on the front side of the resulting solar cell submodule 30, and a bond/seal layer (not shown) and a back sheet (not shown) are formed on the back side of the solar cell submodule 30, that is, on the back side of the substrate 10, and these layers are integrated by vacuum lamination, for example. A thin-film solar cell module is thus obtained.

In this embodiment, a substrate 10 having the structure described above is used, and due to this substrate 10, when forming the layers that constitute the thin-film solar cell, such as the soda lime glass layer, back electrode, CIGS layer (photoelectric conversion layer), CdS buffer layer, ZnO layer and collector electrode, generation of stress due to differences in the linear thermal expansion coefficients of the formed layers is suppressed even when the temperature rises or falls.

In addition, in this embodiment, insulation characteristics are excellent and corrosion of the steel base 12 is prevented because the substrate 10 is used and an insulation layer 14 is formed. Moreover, heat resistance of the substrate 10 is excellent. Thus, a solar cell submodule 30 with excellent durability and storage life can be obtained. For this reason, the thin-film solar cell module also has excellent durability and storage life.

Also, in this embodiment, the substrate 10 is produced by the roll-to-roll system and is flexible. For this reason, the solar cell submodule 30 can also be produced using the roll-to-roll system while the substrate 10 is conveyed in the longitudinal direction L, for example. Thus, manufacturing costs of the solar cell submodule 30 can be reduced because the solar cell submodule 30 is produced using the inexpensive roll-to-roll system. As a result, the cost of a thin-film solar cell module can be reduced.

The present invention is basically as described above. While the substrate with insulation layer and thin-film solar cell of the invention have been described above in detail, the present invention is by no means limited to the above embodiments, and various improvements or design modifications may be made without departing from the scope and spirit of the present invention.

### Example 1

The examples of the substrate with insulation layer of the present invention will be specifically described below.

In this example 1, a mirror-finished aluminum sheet of thickness 0.3 mm and purity 99.5% was used. The aluminum sheet was cleaned with acetone and then ethanol, and then a 0.5 M oxalic acid aqueous solution adjusted to temperature 16° C., and by applying a DC voltage of 40 V, both surfaces of the aluminum sheet were anodized. For anodization, the same aluminum sheet was used as the opposing electrode. By varying the anodization time, anodization was performed so as to result in anodized aluminum film thicknesses of 5, 7, 9, 14, 21, 33, 40 and 70 μm. Aluminum sheets on which anodized aluminum films were formed at various thicknesses were thereby obtained. These were used as substrates.

Then, each substrate on which the anodized alumina film had been formed was washed with pure water and the protective sheet was removed, and then it was additionally washed in acetone and then ethanol, and the components of the adhesive of the protective sheet were thereby removed.

Then, the layers that constitute the thin-film solar cell were formed in the following order on each substrate on which the anodized aluminum film had been formed.

First, on the front surface of the insulation layer, a molybdenum film was formed as a back electrode at a thickness of 800 nm by sputtering.

Then, on the front surface of the molybdenum film, a CIGS layer was formed as a photoelectric conversion layer at a thickness of 1.5-2.0 μm using a multisource vapor deposition machine at 520° C., by simultaneous vapor deposition of copper and selenium, followed by simultaneous vapor deposition of indium, gallium and selenium.

Then, on the front surface of the CIGS layer, a CdS buffer layer was deposited by CBD method at a thickness of 20-100 nm.

Then, on the front surface of the CdS buffer layer, a ZnO layer was deposited by sputtering at a thickness of 0.5-1.5 μm.

Then, on the front surface of the ZnO layer, an aluminum layer was formed as a collector electrode by vapor deposition at a thickness of 200 nm.

In this example 1, each layer that constitutes the thin-film solar cell formed on each substrate was observed using an optical microscope. If any layer peeled, the presence of peeling was judged as “Yes.” If there was no peeling of any layers, the presence of peeling was judged as “No.”

In the results, when the linear thermal expansion coefficient of the front surface of the insulation layer was 6-15 ppm/K (thickness of anodized aluminum layer was 9-40 μm), there was no peeling of any of the layers that constitute the thin-film solar cell. However, peeling occurred when the film thickness was outside that range.

Note that in this example, the linear thermal expansion coefficient of the aluminum sheet is 25 ppm/K, and the linear thermal expansion coefficient of the anodized aluminum film is 4 ppm/K.

TABLE 1

| | Front surface of insulation layer | | |
|---|---|---|---|
| | | Linear thermal | Presence |
| | Film thickness | expansion | of |
| | (μm) | coefficient (ppm/K) | peeling |
| Experimental | 9 | 15 | No |
| example 1 | | | |
| Experimental | 14 | 9.5 | No |
| example 2 | | | |
| Experimental | 21 | 8 | No |
| example 3 | | | |
| Experimental | 33 | 6 | No |
| example 4 | | | |
| Experimental | 40 | 6 | No |
| example 5 | | | |
| Experimental | 7 | 17 | Yes |
| example 6 | | | |
| Experimental | 70 | 5 | Yes |
| example 7 | | | |
| Experimental | 5 | 20 | Yes |
| example 8 | | | |

### Example 2

In this example, anodization was performed under the same conditions as in the above example 1, so as to result in anodized aluminum film thicknesses of 5, 9, 12, 14, 21, 40 and 70 μm on respective aluminum sheets. Aluminum sheets on which anodized aluminum films were formed at various thicknesses were thereby obtained. These were used as substrates.

As the layers that constitute the thin-film solar cell, on each substrate, a soda lime glass layer of thickness 200 nm was formed on the front surface of the insulation layer. Then, on top of this soda lime glass layer, similar to example 1, a molybdenum layer as a back electrode, a CIGS layer as a photoelectric conversion layer, a CdS buffer layer, a ZnO layer and an aluminum layer as a collector electrode were formed in that order. Note that the CIGS layer deposition temperature was 450° C.

In this example, each layer that constitutes the thin-film solar cell formed on each substrate was observed using an optical microscope. If any layer peeled, the presence of peeling was judged as “Yes.” If there was no peeling of any layers, the presence of peeling was judged as “No.”

In the results, there was peeling of the layers that constitute the thin-film solar cell when the thickness of the anodized alumina film was 10 μm or less or 33 μm or more. There was no peeling when the film thickness was 12 μm or more or 27 μm or less. When the linear thermal expansion coefficient of the front surface of the insulation layer of the substrate was 7-12 ppm/K, there was no peeling of the layers that constitute the thin-film solar cell.

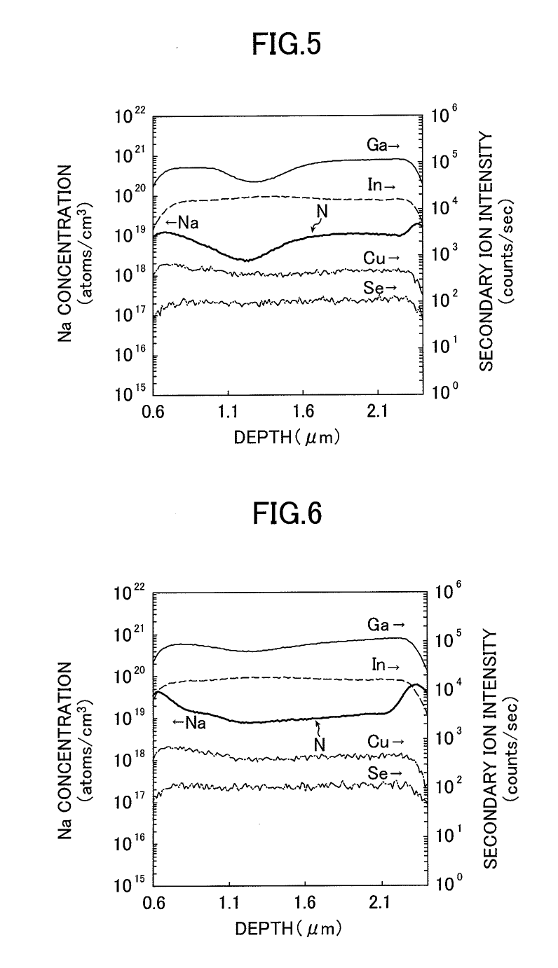

Sodium concentration of the CIGS layer was examined for the samples where there was no peeling of the layers that constitute the thin-film solar cell. An example of results is shown in FIG. 5, together with the secondary ion intensity of copper, gallium, selenium and indium. As shown in FIG. 5, the sodium concentration of the CIGS layer was at least 10¹⁸ (atoms/cm³). Note that the line indicated by the symbol N in FIG. 5 is the concentration profile of sodium concentration.

TABLE 2

| | Front surface of insulation layer | | |
|---|---|---|---|
| | | Linear thermal | Presence |
| | Film thickness | expansion | of |
| | (μm) | coefficient (ppm/K) | peeling |
| Experimental | 14 | 9.5 | No |
| example 10 | | | |
| Experimental | 21 | 8 | No |
| example 11 | | | |
| Experimental | 27 | 7 | No |
| example 12 | | | |
| Experimental | 12 | 12 | No |
| example 13 | | | |
| Experimental | 9 | 15 | Yes |
| example 14 | | | |
| Experimental | 70 | 5 | Yes |
| example 15 | | | |
| Experimental | 5 | 20 | Yes |
| example 16 | | | |

### Example 3

Then, anodization was performed under the same conditions as in the above example 1, so as to result in anodized aluminum film thicknesses of 5, 9, 12, 14, 21, 27 and 70 μm on respective aluminum sheets. Aluminum sheets on which anodized aluminum films were formed at various thicknesses were thereby obtained. These were used as substrates.

As the layers that constitute the solar cell, on each substrate, a soda lime glass layer of thickness 200 nm was formed on the front surface of the insulation layer. Then, on top of this soda lime glass layer, similar to example 1, a molybdenum layer as a back electrode, a CIGS layer as a photoelectric conversion layer, a CdS buffer layer, a ZnO layer and an aluminum layer as a collector electrode were formed in that order. Note that the CIGS layer deposition temperature was 530° C.

In this example 3, each layer that constitutes the thin-film solar cell formed on each substrate was observed using an optical microscope. If any layer peeled, the presence of peeling was judged as “Yes.” If there was no peeling of any layers, the presence of peeling was judged as “No.”

In this example 3, when the linear thermal expansion coefficient of the front surface of the insulation layer of the substrate was 12-27 ppm/K, a good result was obtained without peeling of the layers that constitute the solar cell.

Note that in example 3 as well, sodium concentration of the CIGS layer was examined for the samples where there was no peeling of the layers that constitute the thin-film solar cell. An example of results is shown in FIG. 6, together with the secondary ion intensity of copper, gallium, selenium and indium. As shown in FIG. 6, the sodium concentration of the CIGS layer was at least 10¹⁹ (atoms/cm³). Note that the broken line indicated by the symbol N in FIG. 6 is the concentration profile of sodium concentration.

TABLE 3

| | Front surface of insulation layer | | |
|---|---|---|---|
| | | Linear thermal | Presence |
| | Film thickness | expansion | of |
| | (μm) | coefficient (ppm/K) | peeling |
| Experimental | 14 | 9.5 | No |
| example 20 | | | |
| Experimental | 21 | 8 | No |
| example 21 | | | |
| Experimental | 27 | 7 | No |
| example 22 | | | |
| Experimental | 12 | 12 | No |
| example 23 | | | |
| Experimental | 9 | 15 | Yes |
| example 24 | | | |
| Experimental | 70 | 5 | Yes |
| example 25 | | | |
| Experimental | 5 | 20 | Yes |
| example 26 | | | |

What is claimed is:

1. A substrate with an insulation layer comprising:
at least one metal base; and
an insulation layer laminated on at least one surface of said at least one metal base,
wherein a linear thermal expansion coefficient of a first material that constitutes said insulation layer is 8 ppm/K or less, a linear thermal expansion coefficient of a second material that constitutes said at least one metal base is 17 ppm/K or more, and a linear thermal expansion coefficient on a front surface of said insulation layer on a side opposite to said at least one metal base is 6-15 ppm/K.

2. The substrate with an insulation layer according to claim 1, wherein said insulation layer is made of alumina.

3. The substrate with an insulation layer according to claim 1, wherein said at least one metal base comprises a first metal base which contacts said insulation layer and which is made of aluminum.

4. The substrate with an insulation layer according to claim 1, wherein said insulation layer is an anodized film formed by anodizing said second material made of aluminum.

5. The substrate with an insulation layer according to claim 4, wherein a thickness of said anodized film ranges from 5 μm to 18 μm.

6. The substrate with an insulation layer according to claim 1, wherein said at least one metal base is flexible.

7. A thin-film solar cell comprising:
said substrate with an insulation layer according to claim 1;
a back electrode formed on said insulation layer of said substrate; and
a photoelectric conversion layer formed on said back electrode.

8. The thin-film solar cell according to claim 7, further comprising a soda lime glass layer formed between said insulation layer of said substrate and said back electrode.

9. The thin-film solar cell according to claim 8, wherein said linear thermal expansion coefficient on the front surface of said insulation layer on the side opposite to said at least one metal base is 7-12 ppm/K.

10. The thin-film solar cell according to claim 7, wherein said back electrode made of molybdenum.

11. The thin-film solar cell according to claim 7, wherein said photoelectric conversion layer is made of a CIGS-based semiconductor compound, and said photoelectric conversion layer has a sodium concentration of at least 10¹⁸ (atoms/cm³).

12. The thin-film solar cell according to claim 7, wherein said insulation layer is made of alumina.

13. The thin-film solar cell according to claim 7, wherein said at least one metal base comprises a first metal base which contacts said insulation layer and which is made of aluminum.

14. The thin-film solar cell according to claim 7, wherein said insulation layer is an anodized film formed by anodizing said second material made of aluminum.

15. The thin-film solar cell according to claim 14, wherein a thickness of said anodized film ranges from 5 μm to 18 μm.

16. The thin-film solar cell according to claim 7, wherein said at least one metal base is flexible.
